(19) United States
(12) Patent Application Publication
(10) Pub. No.: US 2016/0177434 A1
(43) Pub. Date: Jun. 23, 2016

(54) METAL COATED FIBRE FORMING APPARATUS AND METHOD OF FORMING A METAL COATED FIBRE

(71) Applicant: ROLLS-ROYCE plc, London (GB)

(72) Inventor: Edwin Stephen TWIGG, Derby (GB)

(73) Assignee: ROLLS-ROYCE plc, London (GB)

(21) Appl. No.: 14/957,050

(22) Filed: Dec. 2, 2015

(30) Foreign Application Priority Data
Dec. 17, 2014 (GB) 1422427.3

(51) Int. Cl. C23C 14/18; H01J 37/34; C23C 14/34

(52) U.S. Cl. CPC C23C 14/185; C23C 14/3414; C23C 14/3485; H01J 37/3426; H01J 37/3467

(57) ABSTRACT

A method of forming a metal coated fibre (2). The method comprises: providing a sputter coating apparatus (10) comprising a deposition chamber (12) containing a target filament (6); applying a negative direct current biasing voltage to the filament (6); wherein the bias is alternately pulsed between a high power condition and a low power condition.

### FIELD OF THE INVENTION

The present invention relates to an apparatus for forming a metal coated fibre, particularly though not exclusively, an apparatus forming a metal coated fibre suitable for use in a Metal Matrix Composite (MMC) material.

### BACKGROUND TO THE INVENTION

MMC materials comprise a plurality of filaments (usually formed of a ceramic filament such as silicon carbide, though metal filaments are also used) within a metal matrix (such as titanium or titanium alloy). A method of forming a high quality MMC is by arranging a plurality of metal coated ceramic filaments around a mandrel, and consolidating the filaments under high temperatures and pressures to form a solid article. A first step in producing MMC materials is therefore providing the metal coated ceramic filaments, typically referred to as Matrix Coated Fibre (MCF)

One known method involves sputter coating a ceramic filament within a sputter coating apparatus. GB 2243844 describes one such arrangement. In some cases, a positive biasing voltage is provided to the filament, which will attract negatively charged metal ions to the filament, thereby increasing deposition rates. Biasing involving radio frequency AC current is also known, for example from U.S. Pat. No. 4,885,069. Using this method, ion polishing occurs during the negative part of cycle via re-sputtering, and retention of the coating material in the positive part. A further known method of forming a metal coated ceramic filament comprises electron beam physical vapour deposition (EBPVD). In EBPVD, bombarding a target with high energy electrons from an electron beam melts the surface thus ejecting atoms from the target creating a vapour. This vapour then condenses on the ceramic fibre, forming a metal coating. Such an arrangement is described in U.S. Pat. No. 6,129,951. Substrate biasing is not known to be in used for basic EBPVD processes.

In sputtering devices, higher operating power generally results in higher deposition rates and biasing is used to create denser substrates and/or modify deposit chemistry. Negative substrate biasing voltage reduces or eliminates porosity in the metal coating. Such methods are commonly used to form relatively dense thin coatings (up to approximately 1 μm), but thicker coatings of 10 μm or more are not common using such methods, as the time required to achieve such thick coatings would be prohibitive.

Provided there is excess atom flux, overall deposition rates can be increased by providing multiple fibre passes through the apparatus, thereby increasing the amount of time the fibre is exposed to the atom vapour. However, again, it has been found to be difficult to obtain high quality coatings having a thickness of 10 μm or more at practical throughput rates without biasing.

The present invention describes a metal coated ceramic fibre forming apparatus which seeks to overcome some or all of the above problems.

### SUMMARY OF THE INVENTION

According to a first aspect of the present invention, there is provided a method of forming a metal coated fibre, the method comprising:

providing a sputter coating apparatus comprising a deposition chamber containing a target filament;
applying a negative direct current biasing voltage to the filament; wherein the bias is alternately pulsed between a high power condition and a low power condition.

It has been found that by pulsing the biasing voltage between relatively high and low levels, a dense coating with a practical surface finish can be achieved, without excessively heating the fibre, as could be the case using a constant bias voltage, especially at higher operating powers.

The biasing voltage may be pulsed between the high and low voltage conditions at a cycle frequency of between 0.1 Hz and 10 Hz, and may be pulsed between the high and low voltage conditions at a cycle frequency of between 0.5 Hz and 2 Hz, and may be pulsed at a cycle frequency of 1 Hz.

The method may comprise applying the biasing voltage at a 50% duty cycle.

The high power condition may comprise a voltage of between approximately −30 and −100 Volts, and preferably may comprise between −40 and 100 Volts, and may comprise approximately −60 Volts.

The low power condition may comprise approximately 0 Volts.

By using relatively high bias voltage for the high power condition, relatively high energy ions are generated which are effective in densification. On the other hand, by pulsing the bias, the time averaged total power can be controlled to limit heating effects.

According to a second aspect of the present invention there is provided a metal coated fibre forming apparatus comprising:

a sputtering apparatus comprising a deposition chamber configured to contain a target filament; and
a biasing apparatus, wherein the biasing apparatus is configured to provide a biasing voltage to the target filament, the biasing voltage being arranged to pulse between a high power condition and a low power condition.

The apparatus may comprise first and second fibre transport assemblies configured to pass a fibre between the first and second fibre transport assemblies to provide a plurality of fibre loops located within the deposition chamber, and to apply a biasing voltage to the fibre.

Each fibre transport arrangement may comprise a plurality of pulleys. Each pulley may comprise a conductive material, and the fibre biasing arrangement may comprise a power supply electrically connected to one or both of the first and second fibre transport assemblies. Advantageously, voltage can be applied to each loop of fibre through the pulleys. This ensures that a substantially consistent bias voltage can be applied to all sections of the fibre, such that coating quality can be controlled during each pass through the atom flux created by the sputtering process as full coating thickness is built up. Each pulley arrangement may be electrically isolated from the chamber and other structures attached to or within the chamber.

The first and second fibre transport assemblies may be arranged such that the fibres are spaced a distance apart within the apparatus such that there is substantially no interference between the electrical fields caused by the biasing voltage. The distance may be approximately 5 mm or more. By spacing the fibres approximately 5 mm apart, it has been found that the deposition rate is not compromised as interference between the electrical fields surrounding the fibres can be minimised thereby maximising the number of passes that can be accommodated within the available space and hence net material deposition. This combination helps to maximise fibre throughput as efficiently as possible.

The filament may comprise any of silicon carbide, alumina, and glass fibre, and the metal coating may comprise titanium or titanium alloy. The filament may comprise a tungsten or carbon core.

### BRIEF DESCRIPTION OF THE DRAWINGS

FIG. 1 shows a cross sectional view of a metal coated fibre;

FIG. 2 shows a schematic cross sectional view of a metal coating forming apparatus in accordance with the present invention;

FIG. 3 shows a simplified and exploded view of the pulley arrangement and fibre paths.

FIGS. 4a and 4b shows a generalised view and a specific example of a bias waveform; for use in the disclosed method; and

FIGS. 5a to 5d are longitudinal cross sections of part of apparatus to show fibre arrangements that are possible whilst marinating the necessary fibre separation distance.

### DETAILED DESCRIPTION

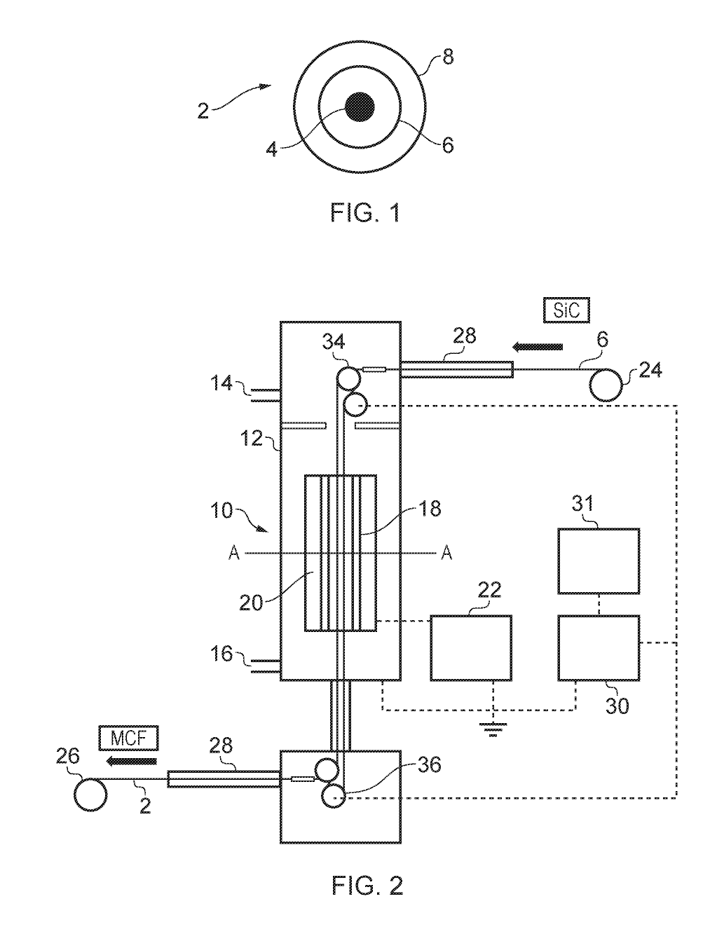

FIG. 1 shows a cross section through a fully formed metal coated ceramic fibre 2. The fibre 2 comprises multiple layers including a core 4 typically formed of a tungsten or carbon filament. The core 4 is surrounded by a ceramic filament 6 comprising silicon carbide (SiC). Other types of ceramic fibre such as alumina may also be used. Surrounding the ceramic filament 6 is a metal coating 8, which in this case comprises titanium or titanium alloy. This metal coating becomes the matrix material of the solid metal matrix composite after densification of many coated fibres in a downstream manufacturing process. Again, other coatings could comprise other metallic materials such as aluminium, metal alloys or multiple layers of different materials or alloys if multiple cathodes are employed.

FIG. 2 shows a metal coated ceramic fibre forming apparatus 10. The apparatus 10 comprises an airtight vacuum chamber 12 arranged to maintain a low pressure environment within the chamber 12. The low pressure environment, about 0.5 Torr for example, is maintained via a vacuum pump (not shown) which draws gas out of the container 12 through a gas outlet 14, whilst at the same time a small quantity of an inert gas such as Argon is introduced into the chamber 12 through a gas inlet 16

The chamber 12 contains a hollow cylindrical electrode 18 cooled by a water jacket 20. The electrode 18 acts as a cathode/source for sputtering atoms. In this example, the cathode is of a titanium alloy such as Ti6V4Al alloy, and is electrically connected to an electrode voltage source 22. For clarity, cooling water connections, other internal structures e.g. earthing arrangements and solenoid for plasma confinement are not shown.

A source spool 24 and uptake spool 26 are provided outside of the chamber 12, and a filament 6 is fed from the source spool through the interior of the hollow electrode 18 to the uptake spool via seals 28. The filament on the source spool 24 comprises only the ceramic filament 6, with no metallic coating yet being present. The filament on the uptake spool 26 is the fully coated ceramic fibre 2

The apparatus 10 further comprises first and second fibre transport assemblies 34, 36 located within the chamber 12. The first assembly 34 is located at a top portion of the apparatus 10, and is arranged to receive filament 6 from the source spool 24 via an air-to-vacuum seal 28. The second assembly 36 is located spaced from the first assembly 34 near the bottom of the apparatus 10 and is arranged to guide the fibre to the uptake spool 26, again via an air-to-vacuum seal 28, with the first and second fibre transport assemblies 34, 36 being separated by the electrode 18. The transport assemblies 34, 36 are configured to pass the fibre 2 between the assemblies 34, 36, to provide a plurality of fibre loops within the hollow cathode. Fibre bias to the filament 6 is provided by a power supply 30 electrically connected to the fibre 6 via either or both of the fibre transport assemblies 34, 36.

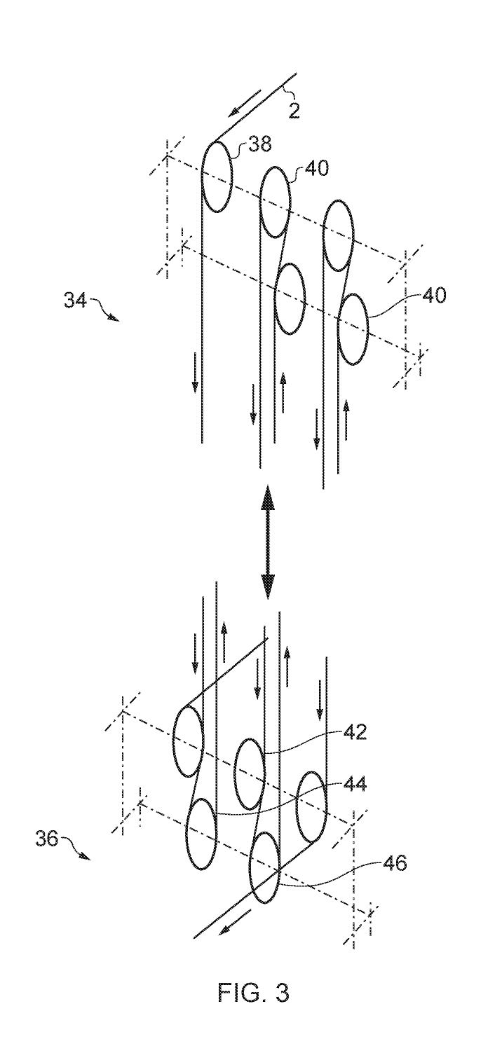

FIG. 3 shows the arrangement of the first and second fibre transport assemblies 34, 36 in more detail. The apparatus 10 includes an entry pulley 38, which is configured to rotate about an axis generally parallel with the longitudinal axis of the electrode 18, and guides the fibre from the inlet air-to-vacuum seal to the first assembly 34. The first assembly 34 includes first and second sets of pulleys 40, 42, and third and fourth sets of pulleys 44, 46 are provided as part of the second assembly 36. In use, fibre is looped around sets of pulleys 40-46 as follows. The first pulley of set 40 receives fibre 6 from the source spool 24. After looping part way around the first pulley of set 40, the fibre traverses the hollow internal space defined by the inner surface of the electrode 18 to the third set of pulleys 44 located at the lower end of the chamber 12. The fibre 6 (now partially coated) loops part way around the third set of pulleys 44 and is then passed to the fourth set of pulleys 46, where the fibre loops around the set of pulleys 46, and back up through the electrode 18 to the second set of pulleys 42. The fibre 6 (partially coated) then passes back to the first set of pulleys 40, and follows a similar route back down through the electrode 18 for another pass. A simplified and exploded view of this path is shown in FIG. 3. After traversing the electrode 18 for approximately 11 passes, the fully coated fibre 2 is passed from the third set of pulleys 44 via exit pulley 48 through pulley the exit air-to-vacuum seal to the uptake spool 26 located outside of the chamber 12.

In use, a negative voltage is applied to the electrode 18 from the sputtering power supply 22 via the cooling jacket creating low pressure plasma which sputters Titanium from the electrode 18. The sputtered material is deposited on the fibre 6, thereby forming the metal coating 8 on the fibre 6 as the fibre passes between the fibre transport assemblies 34, 36 through the electrode 18. Consequently, the thickness of the metal coating 8 increases from 0 at the transfer pulley 38 to around 50 μm or more by the time the fibre 2 is passed to the uptake spool 26. Consequently, the fibre diameter increases during each pass, by around 5 μm in the case of an 11 pass apparatus.

The apparatus 10 further comprises a biasing power supply 30, which is electrically connected to the filament 6 via the first fibre transport assembly 34, and also via the second fibre transport assembly 36. A direct current (DC) negative electrical potential (biasing voltage) is thereby applied to the fibre 2. Bias power is dependent on operating power, i.e. the power applied to the cathode 18. As an example, the main plasma is generated by the voltage source 22 applying approximately 7 kW of electrical power to the cathode 18 to produce a metal coating of around 50 μm via 11-passes. A bias voltage of around −60V total bias power is provided by the biasing power supply 30, to provide a peak power of around 100 W. Outside the chamber, arrangements must be made to ensure that the fibre does not come into contact with any earthed structure, or any structure that is electrically live via other power supplies.

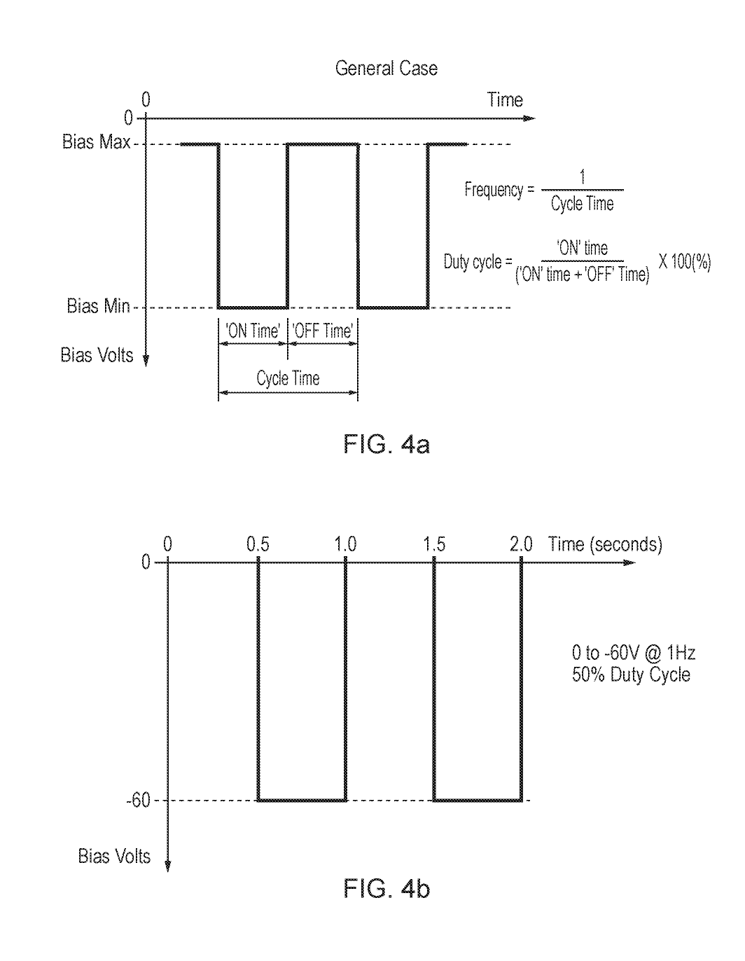

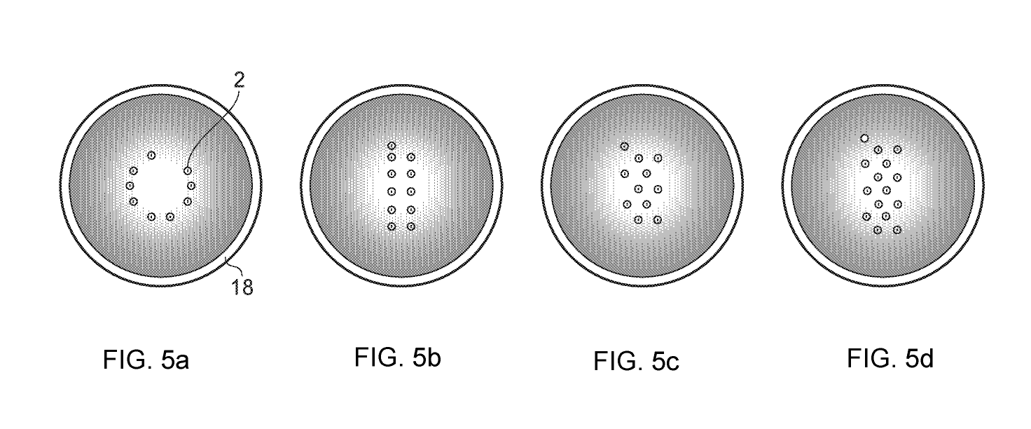

The biasing voltage is pulsed between a low power condition and a high power condition, as shown for example in FIGS. 4a (which shows the general principle of the pulsed bias) and 4b (which illustrates particular a cycle time, voltage and duty cycle). This is achieved by cyclically adjusting the biasing voltage between a high magnitude voltage (say, −60 volts), and a low magnitude voltage (say, 0 volts) to produce a square wave signal. The overall time for a full high condition to low condition cycle would be understood to represent the cycle time. The frequency (in Hz) of the biasing voltage will be understood to be the reciprocal of the cycle time. In this example, the frequency will be approximately 1 Hz, though different frequencies could be used. The proportion of the cycle time in which the biasing voltage is in the high power condition will be understood to represent the duty cycle. In the example shown, to provide the pulsed biasing the power supply 30 output is driven by a function generator 31. The power supply 30 is capable of delivering the required bias power, in this case approximately 100 W in the high power ‘on’ condition, and switching quickly enough to supply the required bias waveform to the fibre.

Without wishing to be restricted to theory, the negative biasing voltage delivered via the metal coating 8 causes electrons to be emitted from the partially coated fibre 2, creating low grade plasma around the fibre 2. This causes ionisation of the inert gas (e.g. argon) atoms within the active region of the plasma generator inside the electrode 18 to produce positive ions which are then attracted back toward the negatively charged fibre. These inert gas ions are sufficiently energetic to nudge deposited titanium atoms around the surface of the metal coating on the fibre 2, flattening asperities to produce a dense, smooth coating 8.

The bias is normally conducted via the metal coating, so whilst power is applied to all pulleys, the bare SiC fibre (pass 1) entering the active region inside the cathode 18 will carry little or no bias voltage from the top pulley system, though it will carry some bias voltage via the bottom pulley system since it will have a coating when it arrives there. Clearly a conductive fibre or wire would carry bias voltage from all pulleys, top and bottom.

The bias must have a sufficiently high power to produce the desired density, and so voltages, frequency and duty cycle must be tuned in accordance with the deposition rate, which is in turn controlled by the power provided by the sputtering power supply 22 and the conditions within the chamber 12. However, it has been found that where adjacent fibres passes are spaced less than 5 mm, the low grade plasma fields produced by the bias around individual fibres passes interfere with one another, thereby reducing the deposition rate. Consequently, the arrangement of the present invention allows biasing voltages to be applied, thereby producing and dense and uniform metal coating, without impacting deposition rates.

It has been found by the inventor by extensive experimentation, that whilst biasing results in a dense metal coating with a smooth surface, if biasing is too aggressive, the fibre coating can be overheated, resulting in excessive reaction with the SiC substrate, a surface that is too smooth to provide a key for binder in downstream processing, and can even melt the metal coating. If biasing is not applied, or is not aggressive enough, the metal coating will not be dense, and the surface will be rough.

Similarly, for a given bias, too high a deposition rate resulting from high operating power can result in porous, rough coatings, hence biasing conditions need to be matched to the operating conditions.

Reducing the aggression of static biasing i.e. always on, to avoid overheating, can be achieved by reducing the bias voltage—however this is thought to reduce the number of ions available due to reduced bias voltage and also reduces the energy of those ions rendering the bias even less effective. This is of particular interest since, should the situation arise where the bias voltage would need to be reduced such that ionisation of argon did not occur, then the bias would be ineffective. In such cases, it would be necessary to limit the operating power and deposition rate such that a static bias was possible—however that in turn limits throughput and machine potential is compromised.

It has been discovered by the inventor that the peak bias voltage is most important in determining the surface coating properties (such as surface roughness and density). The present invention thereby overcomes these problems by alternating the bias power between a high power condition and a low power condition. The high power condition ensures that the required surface properties are achieved, while the low power condition allows the fibre to cool. Since the cycle time of switching between the high and low power conditions is relatively short in comparison to the time the fibre spends in the machine (which may be of the order of several minutes or hours), a substantially uniform coating can be applied.

It has been found by the inventors that multiple passes of biased fibre have the advantage of increasing residence time, and hence overall collection rate, but to ensure coating quality for each fibre pass biasing must be applied to each fibre strand passing through the coating region, and not just at entry or exit as described in GB2243844. Applying bias power for all fibre passes via a single strand of fibre, at the exit for example, would result in the whole bias voltage passing through that single strand, causing excessive heating and fibre damage, and probably fibre breakage. Consequently, by providing separate conductive pulleys, biasing voltage can be applied to the filament without excessively heating the fibre.

It has also been found by the inventors that interference between low grade plasma fields around individual fibres created by fibre biasing compromises deposition rate, and hence makes fibre positioning important. Consequently, by providing a spacing between fibres as described herein, reduced deposition rates due to interference between plasma fields around individual fibres is avoided.

While the invention has been described in conjunction with the exemplary embodiments described above, many equivalent modifications and variations will be apparent to those skilled in the art when given this disclosure. Accordingly, the exemplary embodiments of the invention set forth above are considered to be illustrative and not limiting. Various changes to the described embodiments may be made without departing from the spirit and scope of the invention.

Though the specific embodiment is described as having a 5 mm fibre separation between fibres, it will be understood that the distance over which fibre to fibre interaction occurs will in part depend on the strength of the magnetic field which confines both the main sputtering plasma and low grade plasma around the fibre created by the bias. In general the higher the magnetic field the smaller the range of influence and in principle the closer the fibres can be to each other. However, the magnetic field influences the overall sputtering efficiency hence there will be limited scope for adjusting the magnetic field to permit smaller fibre to fibre distances and hence increasing the maximum number of passes even further without potentially compromising deposition rate.

Different biasing voltages and duty cycles could be employed, depending on the required coating thickness, operating power (coating rate) and the materials of the fibre. For example, duty cycles of between 30% and 60% have been shown to be effective (i.e. with the biasing pulsed at the higher power condition for between 30% and 60% of the time respectively) It is thought that much higher frequency bias pulsing could be employed, such as for example at 100 Hz or greater. The low power condition could be operated at a voltage having a magnitude greater than 0.

Other fibre materials would be suitable e.g. Alumina fibre, though the method would be suitable for any continuous fibre e.g. glass, fibre optic, metal wire etc. Metal or alloy coatings could be applied to suit the fibre substrate and intended end use and not purely for use in metal matrix composites.

1. A method of forming a metal coated fibre, the method comprising:
providing a sputter coating apparatus comprising a deposition chamber containing a target filament;
applying a negative direct current biasing voltage to the filament; wherein the bias is alternately pulsed between a high power condition and a low power condition.

2. A method according to claim 1, wherein the biasing current is pulsed between the high and low voltage conditions at a cycle frequency of between 0.1 Hz and 10 Hz.

3. A method according to claim 1, wherein the method comprises applying the biasing current at a 50% duty cycle.

4. A method according to claim 1, wherein the high power condition comprises a voltage of between approximately −30 and −100 Volts.

5. A method according to claim 1, wherein the low power condition comprises approximately 0 Volts.

6. A method according to claim 1, wherein the filament comprises any of silicon carbide, alumina, and glass fibre.

7. A method according to claim 1, wherein the metal coating comprises titanium or titanium alloy.

8. A metal coated fibre forming apparatus comprising:
a sputtering apparatus comprising a deposition chamber configured to contain a target filament; and
a biasing apparatus, wherein the biasing apparatus is configured to provide a biasing voltage to the target filament, the biasing voltage being arranged to pulse between a high power condition and a low power condition.

9. An apparatus according to claim 8, wherein the apparatus comprises first and second fibre transport assemblies configured to pass a fibre between the first and second fibre transport assemblies to provide a plurality of fibre loops located within the hollow cathode, and to apply a biasing voltage to the fibre.

10. An apparatus according to claim 9, wherein each fibre transport arrangement comprises a plurality of pulleys, each pulley comprising a conductive material, and wherein the fibre biasing arrangement further comprises a power supply electrically connected to one or both of the first and second fibre transport assemblies.

11. An apparatus according to claim 8, wherein the first and second fibre transport assemblies are arranged such that the fibres are spaced a distance apart within the apparatus such that there is substantially no interference between the electrical fields caused by the biasing current.

12. An apparatus according to claim 11, wherein the distance is approximately 5 mm or more.

13. An apparatus according to claim 8, wherein the filament comprises any of silicon carbide, alumina, and glass fibre.

14. An apparatus according to claim 13, wherein the metal coating comprises titanium or titanium alloy.
